(19) United States
(12) Patent Application Publication
(10) Pub. No.: US 2019/0180666 A1
(43) Pub. Date: Jun. 13, 2019

(54) SHIFT REGISTER, GATE DRIVING CIRCUIT, DISPLAY DEVICE, AND GATE DRIVING METHOD

(71) Applicants: BOE Technology Group Co., Ltd., Beijing (CN); Chengdu BOE Optoelectronics Technology Co., Ltd., Sichuan (CN)

(72) Inventors: Yong YU, Beijing (CN); Chuanyan LAN, Beijing (CN); Taehyun KIM, Beijing (CN); Qing LIU, Beijing (CN)

(21) Appl. No.: 16/138,133

(22) Filed: Sep. 21, 2018

(30) Foreign Application Priority Data
Dec. 8, 2017 (CN) 201711294665.8

(51) Int. Cl. G09G 3/20; G11C 19/28

(52) U.S. Cl. CPC G09G 3/20; G09G 2300/0809; G09G 2310/0286; G11C 19/287

(57) ABSTRACT

A shift register includes a gate driving signal generating sub-circuit, a plurality of first signal output control sub-circuits, second signal output control sub-circuits, and signal output terminals. Each first signal output control sub-circuit and the corresponding one of the second signal output control sub-circuits coupled thereto are configured to: during one or more time periods in a period of displaying one frame of image, transmit a gate driving signal output by the gate driving signal generating sub-circuit to a corresponding one of the signal output terminals and output the gate driving signal through the corresponding one of the signal output terminals, and during other time periods, transmit the first input signal received by the first signal input terminal to a corresponding one of the signal output terminals and output the first input signal through the corresponding one of the signal output terminals.

### CROSS-REFERENCE TO RELATED APPLICATION

This application claims priority to Chinese Patent Application No. 201711294665.8, filed on Dec. 8, 2017, the contents of which are incorporated herein by reference in the entirety.

### TECHNICAL FIELD

The present application relates to the field of display technology, and specifically to a shift register, a gate driving circuit, a display device, and a gate driving method.

### BACKGROUND

The basic principle of organic light emitting diode (OLED) display devices for realizing the display of one frame of image is to sequentially drive thin film transistors in pixel sub-circuits of each row from top to bottom through respective gate lines, and apply certain voltages to pixel electrodes in pixel sub-circuits of each column from left to right by using respective data lines.

In the existing display device, a gate-drive-on-array (GOA) circuit design is adopted, and the GOA circuit includes a plurality of shift registers, the number of which corresponds to the number of the gate lines, and the shift registers sequentially apply gate driving signals to respective gate lines. As compared with the existing art in which a gate driving circuit and a source driving circuit are fabricated on a glass panel using a chip-on-film (COF) or chip-on-glass (COG) process, the manufacturing process using the GOA circuit design not only saves cost, but also can realize the symmetrical design of panel, and eliminate the bonding area and the peripheral wiring space of the gate driving circuit, thereby realizing the narrow bezel of the display devices and improving productivity and yield of the display devices. However, there are some problems in the design of the existing GOA circuit.

### SUMMARY

In an aspect, the present disclosure provides a shift register including: a gate driving signal generating sub-circuit having a gate driving signal output terminal and configured to output a gate driving signal; a plurality of first signal output control sub-circuits, each of which is coupled to the gate driving signal output terminal of the gate driving signal generating sub-circuit; a plurality of second signal output control sub-circuits, each of which is coupled to a corresponding one of the plurality of first signal output control sub-circuits and a first signal input terminal for receiving a first input signal; and a plurality of signal output terminals. Each of the plurality of first signal output control sub-circuits and a corresponding one of the plurality of second signal output control sub-circuits coupled thereto are commonly coupled to a corresponding one of the plurality of signal output terminals. Each of the plurality of first signal output control sub-circuits and the corresponding one of the plurality of second signal output control sub-circuits coupled thereto are configured to: during one or more time periods in a period of displaying one frame of image, transmit a gate driving signal output by the gate driving signal generating sub-circuit to a corresponding one of the plurality of the signal output terminals and output the gate driving signal through the corresponding one of the plurality of the signal output terminals, and during other time periods in the period of displaying one frame of image, transmit the first input signal received by the first signal input terminal to a corresponding one of the plurality of signal output terminals and output the first input signal through the corresponding one of the plurality of signal output terminals.

In some embodiments, each of the plurality of first signal output control sub-circuits is coupled to a corresponding one of a plurality of first control signal input terminals, and configured to be turned on or off under control of a first control signal input through the corresponding first control signal input terminal, and transmit, when turned on, the gate driving signal output by the gate driving signal generating sub-circuit to the corresponding one of the plurality of signal output terminals.

In some embodiments, each of the plurality of second signal output control sub-circuits is coupled to a corresponding one of a plurality of second control signal input terminals, and configured to be turned on or off under control of a second control signal input through the corresponding second control signal input terminal, and transmit, when turned on, the first input signal provided to the first signal input terminal to the corresponding one of the plurality of signal output terminals.

In some embodiments, each of the plurality of first signal output control sub-circuits includes a first transistor having a first electrode coupled to the gate driving signal output terminal of the gate driving signal generating sub-circuit, a second electrode coupled to the corresponding signal output terminal and the corresponding second signal output control sub-circuit, and a control electrode coupled to the corresponding first control signal input terminal.

In some embodiments, each of the plurality of second signal output control sub-circuits includes a second transistor having a first electrode coupled to the first signal input terminal, a second electrode coupled to the corresponding first signal output control sub-circuit and the corresponding signal output terminal, and a control electrode coupled to the corresponding second control signal input terminal.

In some embodiments, the gate driving signal generating sub-circuit includes: a first input sub-circuit, a second input sub-circuit, a control sub-circuit, a first output sub-circuit, and a second output sub-circuit. The first input sub-circuit is coupled to a second signal input terminal, a first clock signal input terminal and a first node, and configured to control a level at the first node according to a second input signal input from the second signal input terminal and a first clock signal input from the first clock signal input terminal, the first node being a connection point of the first input sub-circuit and the first output sub-circuit. The first output sub-circuit is coupled to the first node, a second clock signal input terminal and each of the plurality of first signal output control sub-circuits, and configured to output a first gate driving signal to each of the plurality of first signal output control sub-circuits according to the level at the first node and a second clock signal input from the second clock signal input terminal. The second input sub-circuit is coupled to a third signal input terminal, a second node and the first clock signal input terminal, and configured to control a level at the second node according to the first clock signal input from the first clock signal input terminal, the second node being a connection point of the second input sub-circuit and the second output sub-circuit. The second output sub-circuit is coupled to the second node, the first signal input terminal and each of the plurality of first signal output control sub-circuits, and configured to output a second gate driving signal to each of the plurality of first signal output control sub-circuits according to the level at the second node. The control sub-circuit is coupled to the first node, the second node and the first clock signal input terminal, and configured to control the level at the second node according to the level at the first node and the first clock signal input from the first clock signal input terminal.

In some embodiments, the first input sub-circuit includes a third transistor having a first electrode coupled to the second signal input terminal, a second electrode coupled to the first node, and a control electrode coupled to the first clock signal input terminal. The first output sub-circuit includes a fourth transistor and a first capacitor, a first electrode of the fourth transistor being coupled to the second clock signal input terminal, a second electrode of the fourth transistor being coupled to a second end of the first capacitor and each of the plurality of first signal output control sub-circuits, and a control electrode of the fourth transistor being coupled to the first node and a first end of the first capacitor. The second input sub-circuit includes a fifth transistor having a first electrode coupled to the third signal input terminal, a second electrode coupled to the second node, and a control electrode coupled to the first clock signal input terminal. The second output sub-circuit includes a sixth transistor and a second capacitor, a first electrode of the sixth transistor being coupled to the first signal input terminal and a second end of the second capacitor, a second electrode of the sixth transistor being coupled to each of the plurality of first signal output control sub-circuits, and a control electrode of the sixth transistor being coupled to the second node and a first end of the second capacitor. The control sub-circuit includes a seventh transistor having a first electrode coupled to the first clock signal input terminal, a second electrode coupled to the second node, and a control electrode coupled to the first node.

In some embodiments, the shift register includes two first signal output control sub-circuits, two second signal output control sub-circuits, and two signal output terminals.

In another aspect, the present disclosure provides a gate driving circuit including a plurality of the above-described shift registers, and a signal output from each signal output terminal of each shift register is configured to drive one gate line.

In some embodiments, the gate driving signal output by the gate driving signal generating sub-circuit of each shift register is applied to the second signal input terminal of next shift register, and the gate driving signal output by the gate driving signal generating sub-circuit of each shift register includes a first gate driving signal and a second gate driving signal.

In another aspect, the present disclosure provides a display device including the above-described gate driving circuit.

In another aspect, the present disclosure provides a gate driving method for a gate driving circuit including a plurality of the above-described shift registers that are cascaded, the method including: outputting, by respective gate driving signal generating sub-circuits of the plurality of the shift registers, gate driving signals; during one or more time periods in a period of displaying one frame of image, transmitting, by each of the plurality of first signal output control sub-circuits of each shift register and one of the plurality of second signal output control sub-circuits of the shift register coupled thereto, the gate driving signal of the shift register to a corresponding one of the plurality of the signal output terminals of the shift register, and outputting the gate driving signal through the corresponding one of the plurality of signal output terminals, and during other time periods in the period of displaying one frame of image, transmitting, by each of the plurality of first signal output control sub-circuits of each shift register and one of the plurality of second signal output control sub-circuits of the shift register coupled thereto, the first input signal provided to the first signal input terminal a corresponding one of the plurality of signal output terminals of the shift register, and outputting the first input signal through the corresponding one of the plurality of signal output terminals.

### BRIEF DESCRIPTION OF DRAWINGS

FIG. 1 is a schematic diagram illustrating a structure of a shift register according to an embodiment of the present disclosure;

FIG. 2 is a schematic diagram illustrating a structure of first and second signal output control sub-circuits in FIG. 1;

FIG. 3 is an operation timing diagram of a shift register according to an embodiment of the present disclosure;

FIG. 4 is a schematic diagram illustrating a structure of a gate driving signal generating sub-circuit in FIG. 1; and

FIG. 5 is an operation timing diagram of the gate driving signal generating sub-circuit in FIG. 1.

### DETAILED DESCRIPTION

To make those skilled in the art better understand the technical solutions of the present disclosure, a shift register, a gate driving circuit, a display device, and a gate driving method provided by the present disclosure will be described in detail below in conjunction with the accompanying drawing.

An existing GOA circuit includes a plurality of shift registers, the number of which corresponds to the number of gate lines, and the shift registers sequentially apply gate line driving signals to the gate lines. Since the shift register includes a plurality of thin film transistors (TFTs), the shift register occupies large space due to large number of thin film transistors, which correspondingly causes large space occupied by the existing GOA circuit, thereby failing to realize a narrow bezel in a display device. Especially in the case where the shift register includes a storage capacitor, since the capacitor occupies a large area, the problem that the existing GOA circuit occupies large space becomes more significant.

Accordingly, the present disclosure provides, inter alia, a shift register, a gate driving circuit, a display device and a gate driving method, which substantially obviate one or more of the problems due to limitations and disadvantages of the related art. In an aspect, embodiments of the present disclosure provide a shift register including: a gate driving signal generating sub-circuit having a gate driving signal output terminal and configured to generate and output a gate driving signal; a plurality of first signal output control sub-circuits, each of which is coupled to the gate driving signal output terminal of the gate driving signal generating sub-circuit; a plurality of second signal output control sub-circuits, each of which is coupled to a corresponding one of the plurality of first signal output control sub-circuits and a first signal input terminal for receiving a first input signal; and a plurality of signal output terminals. Each of the plurality of first signal output control sub-circuits and a corresponding one of the plurality of second signal output control sub-circuits coupled thereto are commonly coupled to a corresponding one of the plurality of signal output terminals. Each of the plurality of first signal output control sub-circuits and the corresponding one of the plurality of second signal output control sub-circuits coupled thereto are configured to: during one or more time periods in a period of displaying one frame of image, transmit a gate driving signal output by the gate driving signal generating sub-circuit to a corresponding one of the plurality of signal output terminals and output the gate driving signal through the corresponding one of the plurality of signal output terminals, and during other time periods in the period of displaying one frame of image, transmit the first input signal received by the first signal input terminal to a corresponding one of the plurality of signal output terminals and output the first input signal through the corresponding one of the plurality of signal output terminals.

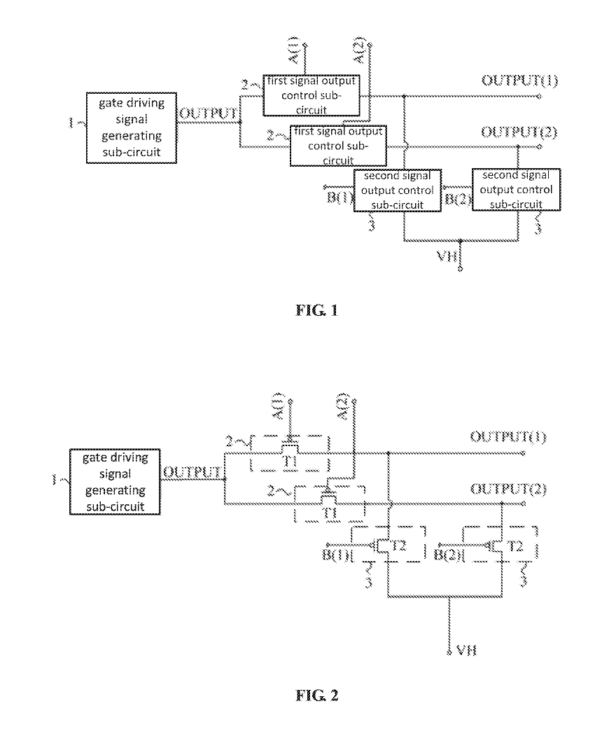

FIG. 1 illustrates a shift register according to an embodiment of the present disclosure by taking a case where each of the numbers of the first signal output control sub-circuits, the second signal output control sub-circuits, and the signal output terminals is two as an example. As illustrated in FIG. 1, the shift register according to an embodiment of the present disclosure may include a gate driving signal generating sub-circuit 1, two first signal output control sub-circuits 2, two second signal output control sub-circuits 3, and two signal output terminals OUTPUT(1) and OUTPUT(2). The number of the first signal output control sub-circuits 2, the number of the second signal output control sub-circuits 3, and the number of the signal output terminals are the same and the first signal output control sub-circuits, the second signal output control sub-circuits, and the signal output terminals are in one-to-one correspondence. Each of the first signal output control sub-circuits 2 is coupled to the gate driving signal generating sub-circuit 1, a corresponding signal output terminal, and a corresponding one of the first control signal input terminals A(1) and A(2), and each of the second signal output control sub-circuits 3 is coupled to a corresponding first signal output control sub-circuit 2, a corresponding signal output terminal, a corresponding one of the second control signal input terminals B(1) and 13(2), and the first signal input terminal VH. The gate driving signal generating sub-circuit 1 has a gate driving signal output terminal OUTPUT for outputting a gate driving signal, and the first signal output control sub-circuit 2 is configured to transmit a gate driving signal output by the gate driving signal generating sub-circuit 1 to the corresponding signal output terminal and output the gate driving signal through the corresponding signal output terminal, under control of a first control signal input from the corresponding first control signal input terminal. The second signal output control sub-circuit 3 is configured to transmit a first input signal input from the first signal input terminal VH to the corresponding signal output terminal and output the first input signal through the corresponding signal output terminal when the gate driving signal is not input from the signal output terminal, under control of a second control signal input from the corresponding second control signal input terminal. That is to say, during one or more time periods in a period of displaying one frame of image, the first signal output control sub-circuit 2 and the second signal output control sub-circuit 3 coupled thereto may transmit the gate driving signal to a corresponding signal output terminal, and during other time periods in the period of displaying one frame of image, the first signal output control sub-circuit 2 and the second signal output control sub-circuit 3 coupled thereto may transmit the first input signal input from the first signal input terminal VH to the corresponding signal output terminal.

The drawings illustrate the shift register according to the embodiments of the present disclosure by taking a case where each of the numbers of the first signal output control sub-circuits, the second signal output control sub-circuits, and the signal output terminals is two as an example, but the present disclosure is not limited thereto. The numbers of the first signal output control sub-circuits, the second signal output control sub-circuits, and the signal output terminals may be any positive integer greater than or equal to 2.

In the shift register according to the embodiments of the present disclosure, during the operation of the shift register, each of the first signal output control sub-circuits may output, under control of the first control signal input from a corresponding first control signal input terminal, the gate driving signal generated by the gate driving signal generating sub-circuit through a corresponding signal output terminal, and each of the second signal output control sub-circuits may output, under control of the second control signal input from a corresponding second control signal input terminal, the first input signal input from the first signal input terminal through a corresponding signal output terminal when the gate driving signal is not output from the signal output terminal. Therefore, each signal output terminal of the shift register may drive a corresponding one of the gate lines, and one shift register may drive multiple gate lines due to the plurality of the signal output terminals of the shift register, which may decrease the number of shift registers in the gate driving circuit, and decrease the space occupied by the gate driving circuit accordingly, thereby facilitating the realization of the narrow bezel of the display panel,

In some embodiments, each of the plurality of first signal output control sub-circuits is coupled to a corresponding one of the plurality of first control signal input terminals, and configured to be turned on or off under control of a first control signal input through the corresponding first control signal input terminal, and transmit, when turned on, the gate driving signal output by the gate driving signal generating sub-circuit to a corresponding one of the plurality of signal output terminals. Each of the plurality of second signal output control sub-circuits is coupled to a corresponding one of the plurality of second control signal input terminals, and configured to be turned on or off under control of a second control signal input through the corresponding second control signal input terminal, and transmit, when turned on, the first input signal received by the first signal input terminal to a corresponding one of the plurality of signal output terminals.

FIG. 2 illustrates an example of the first and second signal output control sub-circuits. As illustrated in FIG. 2, the first signal output control sub-circuit 2 may include a first transistor T1, which has a first electrode coupled to the gate driving signal output terminal of the gate driving signal generating sub-circuit 1, a second electrode coupled to a corresponding one of the signal output terminals OUTPUT(1) and OUTPUT(2) and the corresponding second signal output control sub-circuit 3, and a control electrode coupled to a corresponding one of the first control signal input terminals A(1) and A(2).

Specifically, the first control signal input terminal may control the corresponding first transistor T1 to be turned on or off, and accordingly, may control whether the gate driving signal output by the gate driving signal generating sub-circuit 1 is transmitted to the signal output terminal corresponding to the first transistor T1 and output from the signal output terminal. The first signal output control sub-circuit 2 has a simple structure, is easy to control, and has a low cost.

As illustrated in FIG. 2, the second signal output control sub-circuit 3 may include a second transistor T2, which has a first electrode coupled to the first signal input terminal VH, a second electrode coupled to the corresponding first signal output control sub-circuit 2 and a corresponding one of the signal output terminals OUTPUT(1) and OUTPUT(2), and a control electrode coupled to a corresponding one of the second control signal input terminals B(1) and B(2).

Specifically, the second control signal input terminal may control the corresponding second transistor T2 to be turned on or off, and accordingly, may control whether the first input signal input from the first signal input terminal VH is transmitted to the signal output terminal corresponding to the second transistor T2 and output from the signal output terminal. The second signal output control sub-circuit 3 has a simple structure, is easy to control, and has a low cost.

In the embodiments of the present disclosure, one shift register may drive multiple gate lines corresponding to the plurality of the signal output terminals. As such, the wiring and the timing of the shift register are simple, which facilitates control of the gate lines.

Specifically, it is illustrated by taking a case where each of the numbers of the first signal output control sub-circuits, the second signal output control sub-circuits, and the signal output terminals in FIG. 2 is two as an example. As illustrated in FIG. 2, the shift register includes two first control signal input terminals A(1) and A(2) and two second control signal input terminals B(1) and B(2). The first control signal input terminals A(1) and A(2) control the two first transistors T1 to be turned on or off, respectively, and correspondingly control the gate driving signal output by the gate driving signal generating sub-circuit I to be output through the signal output terminal OUTPUT(1) or OUTPUT(2). The second control signal input terminals B(1) and B(2) control the two second transistors T2 to be turned on or off, respectively, and correspondingly control the first input signal input from the first signal input terminal VH to be output through the signal output terminal OUTPUT(1) or OUTPUT (2).

It should be noted that, the transistors employed in the embodiments of the present disclosure may be thin film transistors, field effect transistors, or other types of transistors. Since a source electrode and a drain electrode of the employed transistor are symmetrical, the source electrode and the drain electrode have no difference. In the embodiments of the present disclosure, to distinguish the source electrode from the drain electrode of the transistor, one of the source and drain electrodes is referred to as a first electrode, the other is referred to as a second electrode, and a gate electrode is referred to as a control electrode. In addition, the transistors may be divided into N type transistors and P type transistors according to the characteristic of the transistors, and the embodiments of the present disclosure are described by taking P-type transistors as an example, in which the transistor is turned off when a high level is input to its gate electrode and turned on when a low level is input to its gate electrode. Needless to say, the transistors employed in the embodiments of the present disclosure may also be N-type transistors, each of which is turned on when a high level is input to its gate electrode and turned off when a low level is input to its gate electrode.

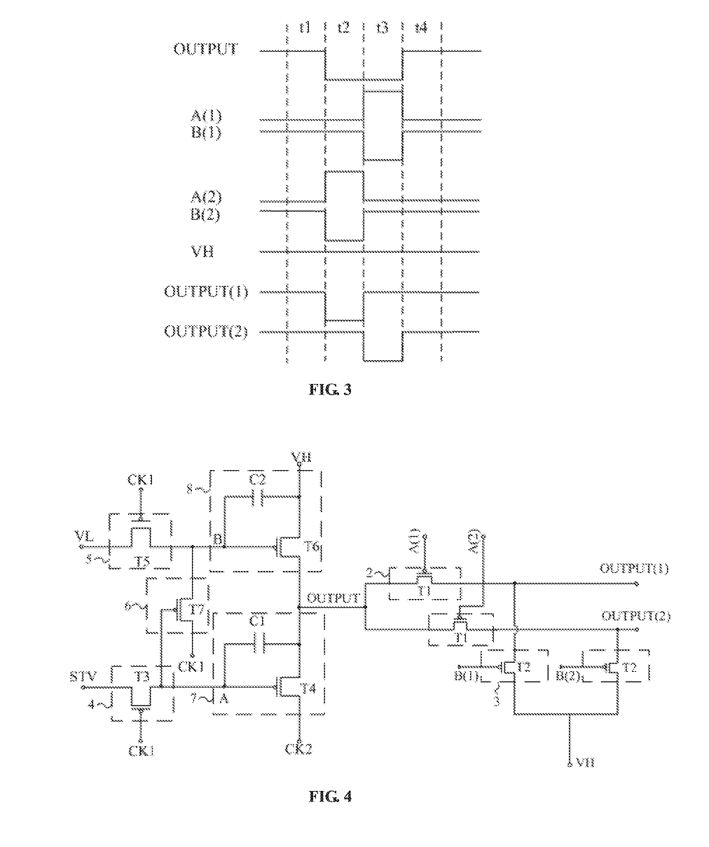

To facilitate the understanding of the driving principle of the shift register driving multiple gate lines by those skilled in the art, the operation process of the shift register will be described in detail below with reference to FIGS. 2 and 3.

As illustrated in FIGS. 2 and 3, the operation process of the display device displaying one frame of image may be divided into time periods t1 to t4. During the time period t1, the gate driving signal output from the gate driving signal output terminal OUTPUT of the gate driving signal generating sub-circuit 1 is a high level signal. At this time, a low level signal is input from each of the first control signal input terminals A(1) and A(2), a high level signal is input from each of the second control signal input terminals B(1) and B(2), and accordingly, the first transistors T1 of the two first signal output control sub-circuits 2 are both turned on, and the second transistors T2 of the two second signal output control sub-circuits 3 are both turned off. In this case, the high level signal output from the gate driving signal output terminal OUTPUT of the gate driving signal generating sub-circuit 1 may be output through the signal output terminals OUTPUT(1) and OUTPUT(2), and accordingly, the two gate lines corresponding to the signal output terminals OUTPUT(1) and OUTPUT(2) may drive the thin film transistors in their corresponding pixel units to be turned off.

During the time period t2, the gate driving signal output from the gate driving signal output terminal OUTPUT of the gate driving signal generating sub-circuit 1 is a low level signal. At this time, a low level signal is input from the first control signal input terminal A(1), a high level signal is input from the second control signal input terminal B(1), a high level signal is input from the first control signal input terminal A(2), a low level signal is input from the second control signal input terminal B(2), accordingly, the first transistor T1 coupled to the signal output terminal OUTPUT(1) is turned on, the second transistor T2 coupled to the signal output terminal OUTPUT(1) is turned off, and the first transistor T1 coupled to the signal output terminal OUTPUT(2) is turned off In this case, the second transistor T2 coupled to the signal output terminal OUTPUT(2) is turned on (that is, the signal output terminal OUTPUT(2) stop outputting the gate driving signal). In this case, the low level signal output from the gate driving signal output terminal OUTPUT of the gate driving signal generating sub-circuit 1 may be output through the signal output terminal OUTPUT(1), the first input signal (i.e., a high level signal) input from the first signal input terminal VH may be output through the signal output terminal OUTPUT(2), accordingly, the gate line corresponding to the signal output terminal OUTPUT(1) may drive its corresponding thin film transistor to be turned on, and the gate line corresponding to the signal output terminal OUTPUT(2) may drive its corresponding thin film transistor to be turned off.

During the time period t3, the gate driving signal output from the gate driving signal output terminal OUTPUT of the gate driving signal generating sub-circuit 1 is a low level signal. At this time, a high level signal is input from the first control signal input terminal A(1), a low level signal is input from the second control signal input terminal B(1), a low level signal is input from the first control signal input terminal A(2), and a high level signal is input from the second control signal input terminal B(2). Accordingly, the first transistor T1 coupled to the signal output terminal OUTPUT(1) is turned off, the second transistor T2 coupled to the signal output terminal OUTPUT(1) is turned on (that is, the signal output terminal OUTPUT(1) stop outputting the gate driving signal), the first transistor T1 coupled to the signal output terminal OUTPUT(2) is turned on, and the second transistor T2 coupled to the signal output terminal OUTPUT(2) is turned off In this case, the low level signal output from the gate driving signal output terminal OUTPUT of the gate driving signal generating sub-circuit 1 may be output through the signal output terminal OUTPUT(2), the first input signal (i.e., a high level signal) input from the first signal input terminal VH may be output through the signal output terminal OUTPUT(1), accordingly, the gate line corresponding to the signal output terminal OUTPUT(1) may drive its corresponding thin film transistor to be turned off, and the gate line corresponding to the signal output terminal OUTPUT(2) may drive its corresponding thin film transistor to be turned on.

During the time period t4, the gate driving signal output from the gate driving signal output terminal OUTPUT of the gate driving signal generating sub-circuit 1 is a high level signal. At this time, a low level signal is input from each of the first control signal input terminals A(1) and A(2), a high level signal is input from each of the second control signal input terminals B(1) and B(2), accordingly, the two first transistors T1 are both turned on, and the tow second transistors T2 are both turned off. In this case, the high level signal output from the gate driving signal output terminal OUTPUT of the gate driving signal generating sub-circuit I may be output through the signal output terminals OUTPUT(1) and OUTPUT(2), accordingly, the two gate lines corresponding to the signal output terminals OUTPUT(1) and OUTPUT(2) may drive their corresponding thin film transistors to be turned off.

When the display device displays the next frame of image, the shift register repeats the operation process of the time periods t1 to t4 to drive two gate lines.

The first control signal input terminal A(1) and the second control signal input terminal B(2) may be combined into one control signal input terminal Accordingly, a high level signal may be input from the control signal input terminal during the time period t1, a low level signal may be input from the control signal input terminal during the time period t2, a high level signal may be input from the control signal input terminal during the time period t3, and a low level signal may be input from the control signal input terminal during the time period t4. It should be noted that, since the output signal output from the gate driving signal output terminal OUTPUT of the gate driving signal generating sub-circuit 1 and the input signal input from the first signal input terminal VH are both high level signals during the time periods t1 and t4, it is also feasible that a low level signal is input from the control signal input terminal during the time period t1 and a high level signal is input from the control signal input terminal during the time period t4. That is to say, during the time periods t1 and t4, the second signal output control sub-circuit 3 may transmit the first input signal (i.e., a high level signal) input from the first signal input terminal VH to the signal output terminal OUTPUT(1), thereby simplifying the structure of the shift register and facilitating the control of the gate lines.

The first control signal input terminal A(2) and the second control signal input terminal B(1) may also be combined into one control signal input terminal. Accordingly, a low level signal may be input from the control signal input terminal during the time period t1, a high level signal may be input from the control signal input terminal during the time period t2, a low level signal may be input from the control signal input terminal during the time period t3, and a high level signal may be input from the control signal input terminal during the time period t4. It should be noted that, since the output signal output from the gate driving signal output terminal OUTPUT of the gate driving signal generating sub-circuit 1 and the input signal input from the first signal input terminal VH are both high level signals during the time periods t1 and t4, it is also feasible that a high level signal is input from the control signal input terminal during the time period t1 and a low level signal is input from the control signal input terminal during the time period t4. That is to say, during the time periods t1 and t4, the second signal output control sub-circuit 3 may transmit the first input signal (i.e., a high level signal) input from the first signal input terminal VH to the signal output terminal OUTPUT(2), thereby simplifying the structure of the shift register and facilitating the control of the gate lines.

It should be noted that the first input signal input from the first signal input terminal VH is a constant level signal. When the transistors T1 and. T2 are P-type transistors, the first input signal is a high level signal shown in FIG. 3. When the transistors T1 and T2 are N-type transistors, the first input signal is a low level signal.

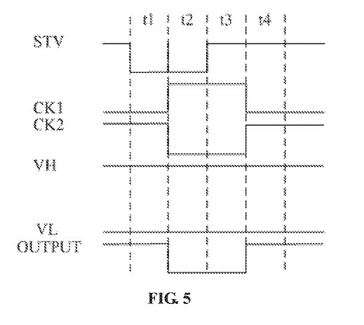

Hereinafter, the specific structure of the gate driving signal generating sub-circuit 1 will be described in detail with reference to FIG. 4.

As illustrated in FIG. 4, the gate driving signal generating sub-circuit 1 may include: a first input sub-circuit 4, a second input sub-circuit 5, a control sub-circuit 6, a first output sub-circuit 7, and a second output sub-circuit 8. The first input sub-circuit 4 is coupled to a second signal input terminal STV, a first clock signal input terminal CK1 and the first node A, and configured to control a level at the first node A according to a second input signal input from the second signal input terminal STV and a first clock signal input from the first clock signal input terminal CK1, the first node A being a connection point of the first input sub-circuit 4 and the first output sub-circuit 7. The first output sub-circuit 7 is coupled to the first node A, a second clock signal input terminal CK2 and each of the first signal output control sub-circuits 2, and configured to input, according to the level at the first node A and a second clock signal input from the second clock signal input terminal CK2, a first gate driving signal to each of the first signal output control sub-circuits 2 through the gate driving signal output terminal OUTPUT. The second input sub-circuit 5 is coupled to a third signal input terminal VL, a second node B and the first clock signal input terminal CK1, and configured to control a level at the second node B according to the first clock signal input from the first clock signal input terminal CK, the second node B being a connection point of the second input sub-circuit 5 and the second output sub-circuit 8. The second output sub-circuit 8 is coupled to the second node B, the first signal input terminal VH and each of the first signal output control sub-circuits 2, and configured to input, according to the level at the second node B, a second gate driving signal to each of the first signal output control sub-circuits 2 through the gate driving signal output terminal OUTPUT. The control sub-circuit 6 is coupled to the first node A, the second node B and the first clock signal input terminal CK1, and configured to control the level at the second node B according to the level at the first node A and the first clock signal input from the first clock signal input terminal CK1. The structure and the timing of the above-described shift register are simple, thereby facilitating the output of the gate driving signal.

In some embodiments, referring to FIG. 4, the first input sub-circuit 4 includes a third transistor T3, the first output sub-circuit 7 includes a fourth transistor T4 and a first capacitor C1, the second input sub-circuit 5 includes a fifth transistor T5, the second output sub-circuit 8 includes a sixth transistor T6 and a second capacitor C2, and the control sub-circuit 6 includes a seventh transistor T7. As such, the first input sub-circuit 4, the first output sub-circuit 7, the second input sub-circuit 5, the second output sub-circuit 8 and the control sub-circuit 6 have a simple structure, are easy to control, and have a low cost.

Specifically, the third transistor T3 has a first electrode coupled to the second signal input terminal STV, a second electrode coupled to the first node A, and a control electrode coupled to the first clock signal input terminal CK1. The fourth transistor T4 has a first electrode coupled to the second clock signal input terminal CK2, a second electrode coupled to a second end of the first capacitor C1 and each of the first signal output control sub-circuits 2, and a control electrode coupled to the first node A and a first end of the first capacitor C1. The fifth transistor T5 has a first electrode coupled to the third signal input terminal VL, a second electrode coupled to the second node B, and a control electrode coupled to the first clock signal input terminal CK1. The sixth transistor T6 has a first electrode coupled to the first signal input terminal VH and a second end of the second capacitor C2, a second electrode coupled to each of the first signal output control sub-circuits 2, and a control electrode coupled to the second node B and a first end of the second capacitor C2. The seventh transistor T7 has a first electrode coupled to the first clock signal input terminal CK1, a second electrode coupled to the second node B, and a control electrode coupled to the first node A.

To facilitate the understanding of the operation principle of the gate driving signal generating sub-circuit 1 by those skilled in the art, the operation process of the gate driving signal generating sub-circuit 1 will be described in detail below with reference to FIGS. 4 and 5.

As illustrated in FIGS. 4 and 5, in the process of displaying one frame of image by the display device, during the time period t1, a low level signal is input from the second signal input terminal STV At this time, a low level signal is input from the first clock signal input terminal CK1, and accordingly, the third transistor T3 and the fifth transistor T5 are turned on, so that the low level signal input from the second signal input terminal STV may charge the first node A via the third transistor T3, the low level signal input from the third signal input terminal VL may be transmitted to the control electrode of the sixth transistor T6 via the fifth transistor T5 to turn on the sixth transistor T6, and accordingly, the high level signal (i.e., the second gate driving signal) input from the first signal input terminal VH may be transmitted to each of the first signal output control sub-circuits 2 via the sixth transistor T6, that is, a high level signal is output through the gate driving signal output terminal OUTPUT of the gate driving signal generating sub-circuit 1.

During the time period t2, a low level signal is input from the second signal input terminal STV. At this time, a high level signal is input from the first clock signal input terminal CK1, a low level signal is input from the second clock signal input terminal CK2, and accordingly, the third transistor T3 and the fifth transistor T5 are turned off. Since the first node A is charged in the time period t1, the first node A is at a low level, so that the fourth transistor T4 and the seventh transistor T7 are turned on. Accordingly, the high level signal input from the first clock signal input terminal CK1 may be transmitted to the control electrode of the sixth transistor T6 via the seventh transistor T7 to turn off the sixth transistor T6, and the high level signal input from the first signal input terminal VH is no longer transmitted to each first signal output control sub-circuit 2. In the meantime, since the fourth transistor T4 is turned on, the low level signal (i.e., the first gate driving signal) input from the second clock signal input terminal CK2 may be transmitted to each of the first signal output control sub-circuits 2 via the fourth transistor T4, that is, a low level signal is output through the gate driving signal output terminal OUTPUT of the gate driving signal generating sub-circuit 1.

During the time period t3, a high level signal is input from the second signal input terminal STV. At this time, a high level signal is input from the first clock signal input terminal CK1, a low level signal is input from the second clock signal input terminal CK2, and accordingly, the high level signal input from the first signal input terminal VH is no longer transmitted to each of the first signal output control sub-circuits 2, and the low level signal (i.e., the first gate driving signal) input from the second clock signal input terminal CK2 is transmitted to each of the first signal output control sub-circuits 2 via the fourth transistor T4, that is, a low level signal is output through the gate driving signal output terminal OUTPUT of the gate driving signal generating sub-circuit 1.

During the time period t4, a high level signal is input from the second signal input terminal STV At this time, a low level signal is input from the first clock signal input terminal CK1, and accordingly, the third transistor T3 and the fifth transistor T5 are turned on. In this case, the high level signal input from the second signal input terminal STV may be transmitted to the control electrode of the fourth transistor T4 via the third transistor T3 to turn off the fourth transistor T4, and the signal input from the second clock signal input terminal CK2 is no longer transmitted to each first signal output control sub-circuit 2. In the meantime, since the fifth transistor T5 is turned on, the low level signal input from the third signal input terminal VL may charge the second node B via the fifth transistor T5 and be transmitted to the control electrode of the sixth transistor T6 to turn on the sixth transistor T6, and accordingly, the high level signal (i.e., the second gate driving signal) input from the first signal input terminal VH may be transmitted to each of the first signal output control sub-circuits 2, that is, a high level signal is output through the gate driving signal output terminal OUTPUT of the gate driving signal generating sub-circuit 1.

In the time period after the time period t4, a signal input from the second signal input terminal STV keeps at a high level. When a high level signal is input from the first clock signal input terminal CK1, the fifth transistor T5 is turned off, and accordingly, the low level signal input from the third signal input terminal VL is no longer transmitted to the control electrode of the sixth transistor T6 via the fifth transistor TS. At this time, since the second node B is charged in the time period t4, the second node B is at a low level, so that the sixth transistor T6 may maintain on, thereby continuously transmitting the high level signal (that is, the second gate driving signal) input from the first signal input terminal VH to each of the first signal output control sub-circuits 2.

When the display device displays a next frame of image, a low level signal is input from the second signal input terminal STV, and the gate driving signal generating sub-circuit 1 repeats the operation process of the time periods t1 to t4 to output the gate driving signal (that is, the first and second gate driving signals).

In another aspect, the embodiments of the present disclosure provide a gate driving circuit including a plurality of the above-described shift registers that are cascaded, and a signal output from each signal output terminal of each shift register is configured to drive one gate line. The gate driving signal output by the gate driving signal generating sub-circuit 1 of each shift register serves as an input signal to the second signal input terminal STV of next shift register, and gate driving signal output by the gate driving signal generating sub-circuit 1 of each shift register includes a first gate driving signal (i.e., a low level signal) and a second gate driving signal (i.e., a high level signal). The gate driving circuit according to the present embodiment has a simple structure and is easy to implement, and one shift register can drive a plurality of gate lines, so that the number of shift registers in the gate driving circuit can be reduced, thereby reducing the space occupied by the gate driving circuit and accordingly realizing an ultra-narrow bezel deign of a display device.

In another aspect, the embodiments of the present disclosure provide a display device including the above-described gate driving circuit. The display device may be any product or component with a display function, such as a mobile phone, a tablet computer, a television, a display, a notebook computer, a digital photo frame, a navigator, or the like. Since the display device according to the present embodiment includes the above-described gate driving circuit and the gate driving circuit occupies small space, a narrow bezel design of the display device can be realized.

In another aspect, the embodiments of the present disclosure provide a gate driving method for a gate driving circuit, and the gate driving circuit includes a plurality of the above-described shift registers that are cascaded. The method includes: outputting, by the gate driving signal generating sub-circuits I of the plurality of the shift registers, gate driving signals; during one or more time periods in a period of displaying one frame of image, transmitting, by each of the plurality of first signal output control sub-circuits 2 of each shift register and one of the plurality of second signal output control sub-circuits 3 of the shift register coupled thereto, a gate driving signal of the shift register to a corresponding one of the plurality of the signal output terminals of the shift register, and outputting the gate driving signal through the corresponding one of the plurality of the signal output terminals, and during other time periods in the period of displaying one frame of image, transmitting, by each of the plurality of first signal output control sub-circuits of each shift registers and one of the plurality of second signal output control sub-circuits of the shift register coupled thereto, the first input signal provided to the first signal input terminal VH to a corresponding one of the plurality of signal output terminals of the shift register, and outputting the first input signal through the corresponding one of the plurality of signal output terminals.

The gate driving method can realize that one shift register drives a plurality of gate lines, and accordingly, the number of shift registers in the gate driving circuit can be reduced, thereby reducing the space occupied by the gate driving circuit, and realizing an ultra-narrow bezel design of a display device.

It can be understood that the foregoing embodiments are merely exemplary embodiments used for describing the principle of the present disclosure, but the present disclosure is not limited thereto. Those of ordinary skill in the art may make various variations and improvements without departing from the spirit and essence of the present invention, and these variations and improvements shall also fall into the protection scope of the present disclosure.

What is claimed is:

1. A shift register, comprising:
a gate driving signal generating sub-circuit having a gate driving signal output terminal and configured to output a gate driving signal;
a plurality of first signal output control sub-circuits, each of which is coupled to the gate driving signal output terminal of the gate driving signal generating sub-circuit;
a plurality of second signal output control sub-circuits, each of which is coupled to a corresponding one of the plurality of first signal output control sub-circuits and a first signal input terminal for receiving a first input signal; and
a plurality of signal output terminals,
wherein each of the plurality of first signal output control sub-circuits and a corresponding one of the plurality of second signal output control sub-circuits coupled thereto are commonly coupled to a corresponding one of the plurality of signal output terminals, and
each of the plurality of first signal output control sub-circuits and the corresponding one of the plurality of second signal output control sub-circuits coupled thereto are configured to: during one or more time periods in a period of displaying one frame of image, transmit a gate driving signal output by the gate driving signal generating sub-circuit to a corresponding one of the plurality of the signal output terminals and output the gate driving signal through the corresponding one of the plurality of the signal output terminals, and during other time periods in the period of displaying one frame of image, transmit the first input signal received by the first signal input terminal to a corresponding one of the plurality of signal output terminals and output the first input signal through the corresponding one of the plurality of signal output terminals.

2. The shift register of claim 1, wherein each of the plurality of first signal output control sub-circuits is coupled to a corresponding one of a plurality of first control signal input terminals, and configured to be turned on or off under control of a first control signal input through the corresponding first control signal input terminal, and transmit, when turned on, the gate driving signal output by the gate driving signal generating sub-circuit to the corresponding one of the plurality of signal output terminals.

3. The shift register of claim 1, wherein each of the plurality of second signal output control sub-circuits is coupled to a corresponding one of a plurality of second control signal input terminals, and configured to be turned on or off under control of a second control signal input through the corresponding second control signal input terminal, and transmit, when turned on, the first input signal received by the first signal input terminal to the corresponding one of the plurality of signal output terminals.

4. The shift register of claim 2, wherein each of the plurality of first signal output control sub-circuits comprises a first transistor having a first electrode coupled to the gate driving signal output terminal of the gate driving signal generating sub-circuit, a second electrode coupled to the corresponding signal output terminal and the corresponding second signal output control sub-circuit, and a control electrode coupled to the corresponding first control signal input terminal.

5. The shift register of claim 3, wherein each of the plurality of second signal output control sub-circuits comprises a second transistor having a first electrode coupled to the first signal input terminal, a second electrode coupled to the corresponding first signal output control sub-circuit and the corresponding signal output terminal, and a control electrode coupled to the corresponding second control signal input terminal.

6. The shift register of claim 1, wherein the gate driving signal generating sub-circuit comprises: a first input sub-circuit, a second input sub-circuit, a control sub-circuit, a first output sub-circuit, and a second output sub-circuit,
the first input sub-circuit is coupled to a second signal input terminal, a first clock signal input terminal and a first node, and configured to control a level at the first node according to a second input signal input from the second signal input terminal and a first clock signal input from the first clock signal input terminal, the first node being a connection point of the first input sub-circuit and the first output sub-circuit,
the first output sub-circuit is coupled to the first node, a second clock signal input terminal and each of the plurality of first signal output control sub-circuits, and configured to output a first gate driving signal to each of the plurality of first signal output control sub-circuits according to the level at the first node and a second clock signal input from the second clock signal input terminal,
the second input sub-circuit is coupled to a third signal input terminal, a second node and the first clock signal input terminal, and configured to control a level at the second node according to the first clock signal input from the first clock signal input terminal, the second node being a connection point of the second input sub-circuit and the second output sub-circuit,
the second output sub-circuit is coupled to the second node, the first signal input terminal and each of the plurality of first signal output control sub-circuits, and configured to output a second gate driving signal to each of the plurality of first signal output control sub-circuits according to the level at the second node, and
the control sub-circuit is coupled to the first node, the second node and the first clock signal input terminal, and configured to control the level at the second node according to the level at the first node and the first clock signal input from the first clock signal input terminal.

7. The shift register of claim 6, wherein the first input sub-circuit comprises a third transistor having a first electrode coupled to the second signal input terminal, a second electrode coupled to the first node, and a control electrode coupled to the first clock signal input terminal,
the first output sub-circuit comprises a fourth transistor and a first capacitor, a first electrode of the fourth transistor being coupled to the second clock signal input terminal, a second electrode of the fourth transistor being coupled to a second end of the first capacitor and each of the plurality of first signal output control sub-circuits, and a control electrode of the fourth transistor being coupled to the first node and a first end of the first capacitor,
the second input sub-circuit comprises a fifth transistor having a first electrode coupled to the third signal input terminal, a second electrode coupled to the second node, and a control electrode coupled to the first clock signal input terminal,
the second output sub-circuit comprises a sixth transistor and a second capacitor, a first electrode of the sixth transistor being coupled to the first signal input terminal and a second end of the second capacitor, a second electrode of the sixth transistor being coupled to each of the first plurality of signal output control sub-circuits, and a control electrode of the sixth transistor being coupled to the second node and a first end of the second capacitor, and
the control sub-circuit comprises a seventh transistor having a first electrode coupled to the first clock signal input terminal, a second electrode coupled to the second node, and a control electrode coupled to the first node.

8. The shift register of claim 1, wherein the shift register comprises two first signal output control sub-circuits, two second signal output control sub-circuits, and two signal output terminals.

9. A gate driving circuit, comprising a plurality of shift registers of claim 1., wherein a signal output from each signal output terminal of each shift register is configured to drive one gate line.

10. A gate driving circuit, comprising a plurality of shift registers of claim 2, wherein a signal output from each signal output terminal of each shift register is configured to drive one gate line.

11. A gate driving circuit, comprising a plurality of shift registers of claim 3, wherein a signal output from each signal output terminal of each shift register is configured to drive one gate line.

12. A gate driving circuit, comprising a plurality of shift registers of claim 4, wherein a signal output from each signal output terminal of each shift register is configured to drive one gate line.

13. A gate driving circuit, comprising a plurality of shift registers of claim 5, wherein a signal output from each signal output terminal of each shift register is configured to drive one gate line.

14. A gate driving circuit, comprising a plurality of shift registers of claim 6, wherein a signal output from each signal output terminal of each shift register is configured to drive one gate line.

15. A gate driving circuit, comprising a plurality of shift registers of claim 7, wherein a signal output from each signal output terminal of each shift register is configured to drive one gate line.

16. A gate driving circuit, comprising a plurality of shift registers of claim 8, wherein a signal output from each signal output terminal of each shift register is configured to drive one gate line.

17. The gate driving circuit of claim 9, wherein the gate driving signal output by the gate driving signal generating sub-circuit of each shift register is applied to the second signal input terminal of next shift register, and the gate driving signal output by the gate driving signal generating sub-circuit of each shift register comprises a first gate driving signal and a second gate driving signal.

18. A display device, comprising the gate driving circuit of claim 9.

19. A gate driving method for a gate driving circuit, the gate driving circuit comprising a plurality of shift registers that are cascaded, each of the plurality of shift registers comprising: a gate driving signal generating sub-circuit having a gate driving signal output terminal and configured to output a gate driving signal; a plurality of first signal output control sub-circuits, each of which is coupled to the gate driving signal output terminal of the gate driving signal generating sub-circuit; a plurality of second signal output control sub-circuits, each of which is coupled to a corresponding one of the plurality of first signal output control sub-circuits and a first signal input terminal for receiving a first input signal; and a plurality of signal output terminals; each of the plurality of first signal output control sub-circuits and a corresponding one of the plurality of second signal output control sub-circuits coupled thereto are commonly coupled to a corresponding one of the plurality of signal output terminals,
the method comprising:
outputting, by respective gate driving signal generating sub-circuits of the plurality of the shift registers, gate driving signals; and
during one or more time periods in a period of displaying one frame of image, transmitting, by each of the plurality of first signal output control sub-circuits of each shift register and one of the plurality of second signal output control sub-circuits of the shift register coupled thereto, a gate driving signal of the shift register to a corresponding one of the plurality of the signal output terminals of the shift register, and outputting the gate driving signal through the corresponding one of the plurality of the signal output terminals, and during other time periods in the period of displaying one frame of image, transmitting, by each of the plurality of first signal output control sub-circuits of each shift register and the one of the plurality of second signal output control sub-circuits of the shift register coupled thereto, the first input signal received by the first signal input terminal to a corresponding one of the plurality of signal output terminals of the shift register, and outputting the first input signal through the corresponding one of the plurality of signal output terminals.
